(19) United States
(12) Patent Application Publication
(10) Pub. No.: US 2025/0329587 A1
(43) Pub. Date: Oct. 23, 2025

(54) THROUGH SILICON VIA

(71) Applicant: INTERNATIONAL BUSINESS MACHINES CORPORATION, ARMONK, NY (US)

(72) Inventors: Lijuan Zou, Albany, NY (US); Tao Li, Slingerlands, NY (US); Ruilong Xie, Niskayuna, NY (US); Chih-Chao Yang, Glenmont, NY (US)

(21) Appl. No.: 18/641,649

(22) Filed: Apr. 22, 2024

(51) Int. Cl. H01L 21/768; H01L 23/48; H01L 23/528

(52) U.S. Cl. CPC H01L 21/76898; H01L 23/481; H01L 23/5286

(57) ABSTRACT

Embodiments of present invention provide a semiconductor structure. The semiconductor structure includes a landing pad in a back-end-of-line structure; a backside power distribution network in a backside dielectric layer; and a through silicon via extending from the backside dielectric layer to the landing pad in the back-end-of-line structure, where the through silicon via has a first portion of a first width and a second portion of a second width and a discontinuous increase in width from the first width of the first portion to the second width of the second portion. A method of forming the same is also provided.

### BACKGROUND

The present application relates to manufacturing of semiconductor integrated circuits. More particularly, it relates to a method of forming through silicon via and the structure of through silicon via formed thereby.

As semiconductor industry moves towards smaller node for increased device density, backside power distribution network (BSPDN) is introduced as a mean to enhance the device density. In the application of BSPDN, one of the key enablers is the connection between the BSPDN and metal levels of back-end-of-line (BEOL) at the frontside of the device, and such connection is usually made in the form of a through silicon via, or more generally a through via.

Generally, because of the large depth of such a through via, it is difficult to accurately land the through via preciously on a landing pad at the metal level of BEOL. Consequently, a much larger through via may be needed in order to land the through via at least partially on the landing pad. The larger through via not only takes up more real estate spaces, but also may cause short to any nearby transistors.

### SUMMARY

Embodiments of present invention provide a semiconductor structure. The semiconductor structure may include a first metal level in a back-end-of-line (BEOL) structure; a second metal level in a backside power distribution network (BSPDN); and a through silicon via (TSV) extending from the second metal level to the first metal level, where the TSV has a first portion and a second portion and a discontinuous increase in width from the first portion to the second portion.

According to one embodiment, the semiconductor structure further includes a landing pad at the first metal level, where the landing pad has a width that is wider than a width of the first portion of the TSV and the first portion of the TSV fully lands on the landing pad at the first metal level.

According to another embodiment, the semiconductor structure further includes a first guiding pad and a second guiding pad and a gap between the first guiding pad and the second guiding pad, where a width of the first portion of the TSV is substantially same as a width of the gap.

In one embodiment, the first and the second guiding pad are horizontally aligned with one or more backside source/drain contacts of one or more transistors.

In another embodiment, the first and the second guiding pad are horizontally aligned with one of one or more backside metal levels of the BSPDN.

In yet another embodiment, the second portion of the TSV partially lands on the first and the second guiding pad such that the discontinuous increase in width of the TSV coincides with a location of the first and the second guiding pad.

In one embodiment, the first portion of the TSV has a first width, and the second portion of the TSV has a second width, and the second width is at least 5% more than the first width.

Embodiments of present invention further provide a method of forming a semiconductor structure. The method includes forming a landing pad at a metal level of a back-end-of-line (BEOL) structure; forming a first and a second guiding pad vertically above the landing pad; forming a backside dielectric layer covering the first and the second guiding pad; creating a second portion of a via opening in the backside dielectric layer, the second portion of the via opening exposing a portion of the first and the second guiding pad and a gap between the first and the second guiding pad; creating a first portion of the via opening through the gap between the first and the second guiding pad, the first portion of the via opening exposing the landing pad; and filling the via opening with a conductive material to form a through silicon via (TSV).

In one embodiment, the gap between the first and the second guiding pad is substantially aligned with the landing pad and a width of the gap is equal to or less than a width of the landing pad.

In another embodiment, forming the first and the second guiding pad includes forming a first and a second dummy contact, the first and the second dummy contact are horizontally aligned with one or more backside source/drain contact of one or more transistors.

In yet another embodiment, forming the first and the second guiding pad includes forming a first and a second dummy metal line, the first and the second dummy metal line are horizontally aligned with one of one or more backside metal levels of a backside power distribution network.

In one embodiment, creating the first portion of the via opening includes etching a region in the gap between the first and the second guiding pad in an etch process that is selective to the first and the second guiding pad.

According to one embodiment, the method further includes forming a backside power distribution network in the backside dielectric layer and a C4 solder.

In one embodiment, the TSV is either connected to the BSPDN or connected to the C4 solder.

### BRIEF DESCRIPTION OF THE DRAWINGS

The present invention will be understood and appreciated more fully from the following detailed description of embodiments of present invention, taken in conjunction with accompanying drawings of which:

FIGS. 1 to 7 are demonstrative illustrations of cross-sectional views of a semiconductor structure at various steps of manufacturing thereof according to one embodiment of present invention;

FIGS. 8 to 13 are demonstrative illustrations of cross-sectional views of a semiconductor structure at various steps of manufacturing thereof according to another embodiment of present invention; and

FIG. 14 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

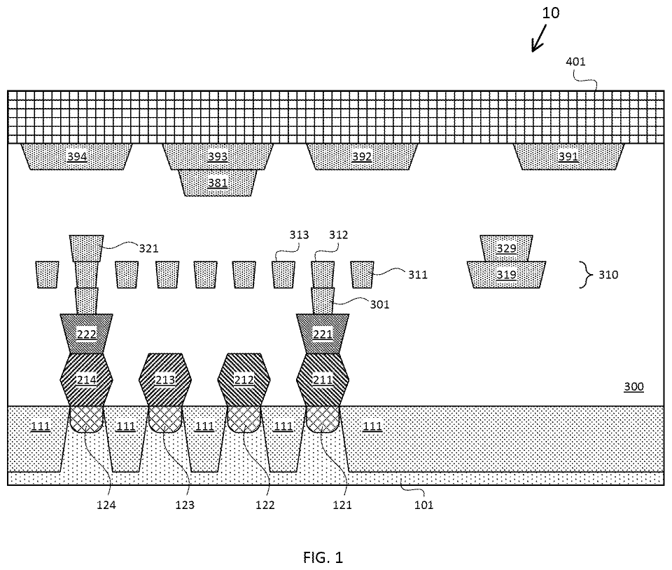

FIG. 1 is a demonstrative illustration of cross-sectional view of a semiconductor structure in a step of manufacturing thereof according to one embodiment of present invention. More specifically, embodiments of present invention provide forming a semiconductor structure 10 that includes one or more transistors on top of a substrate, middle-of-line (MOL) contacts contacting the one or more transistors, and a back-end-of-line (BEOL) that has one or more metal levels on top of the MOL contacts.

For example, as is illustrated in FIG. 1, the semiconductor structure 10 may include one or more source/drain (S/D) regions such as S/D regions 211, 212, 213, and 214 of the one or more transistors. The S/D regions 211, 212, 213, and 214 may be formed on top of a semiconductor substrate 101, and more particularly on top of one or more placeholders 121, 122, 123, and 124 that are formed to be embedded in the semiconductor substrate 101. One or more shallow-trench-isolations (STI's) 111 may be formed in the semiconductor substrate 101 separating the one or more transistors.

Further for example, the semiconductor structure 10 may further include one or more MOL contacts such as a first S/D contact 221 and a second S/D contact 222 contacting the S/D regions 211 and 214 respectively, and a BEOL structure formed on top of and in contact with the one or more MOL contacts. The BEOL structure may be formed in a dielectric layer 300 to include one or more metal levels, such as a first metal level 310 that includes one or more metal lines such as metal lines 311, 312, and 313, and a second metal level that includes one or more metal lines such as metal lines 391, 392, 393, and 394. The first metal level 310 may be a metal level-1 (M1), and the second metal level may be a metal level-x (Mx) where x may be 2, 3, 4, . . . or 9, etc. The one or more metal lines may be interconnected by one or more vias such as a via 321 and a via 381. In one embodiment, one or more of the metal lines such as the metal line 312 may be connected to the first S/D contact 221 through a via 301. The one or more transistors including the S/D regions 211, 212, 213, and 214 may be embedded in the dielectric layer 300.

According to one embodiment, the semiconductor structure 10 may include a landing pad 319 for a through silicon via (TSV) or more generally for a through via. The landing pad 319 may be formed inside the BEOL structure at a level such as at the first metal level 310 and may be conductively connected to other parts of the BEOL structure through, for example, a via 329. Being formed at the first metal level 310, the landing pad 319 may be a conductive landing pad having a horizontal width that is comparable with that of the one or more metal lines 311, 312, and 313 of the first metal level 310. As a M1 in the BEOL structure, the one or more metal lines 311, 312, and 313 and the landing pad 319 may have a substantially same horizontal width, typically ranging from about 50 nm to about 500 nm. The narrowness of the landing pad 319 at the substantially same horizontal width as the metal lines 311, 312, and 313 makes it difficult, if not possible, to land a through via preciously on top of the landing pad 319 through a backside of the structure.

A handling wafer 401 is attached to the BEOL structure and the semiconductor structure 10 is flipped upside-down for further processing from a backside of the structure.

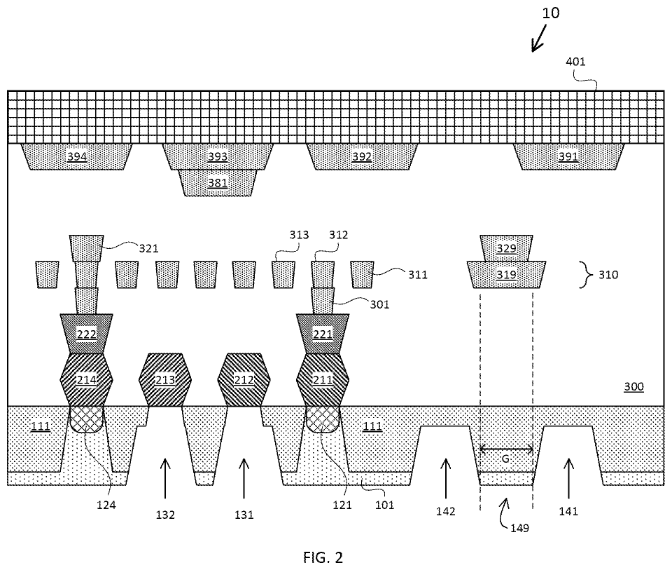

FIG. 2 is a demonstrative illustration of cross-sectional view of a semiconductor structure in a step of manufacturing thereof according to one embodiment of present invention. More particularly, following the step illustrated in FIG. 1, embodiments of present invention provide forming backside S/D contacts by creating opening from backside of the semiconductor structure 10 to expose bottom surfaces of the S/D regions. Hereinafter, processing of the semiconductor structure 10 is performed from the backside of the semiconductor substrate 101 and the description is so provided as if the semiconductor substrate 101 is flipped upside-down. Nevertheless, for the convenience of illustration, drawings of FIGS. 2-7 may continue to be provided in an upside-up fashion.

For example, embodiments of present invention provide creating a first backside contact opening 131 and a second backside contact opening 132 in the semiconductor substrate 101. The first and the second backside contact opening 131 and 132 may expose the placeholders 122 and 123 respectively, and the exposed placeholders 122 and 123 may be selectively removed subsequently. Embodiments of present invention may therefore expose the bottom surfaces of the S/D regions 212 and 213.

According to one embodiment of present invention, in the process of creating the first and the second backside contact opening 131 and 132 from the backside of the semiconductor structure 10, embodiments of present invention provide creating a first recess 141 and a second recess 142 in the semiconductor substrate 101. In one embodiment, the first and the second recess 141 and 142 may be made into the STI 111. The first and the second recess 141 and 142 may be made strategically such that a gap 149 between the first recess 141 and the second recess 142 may be vertically aligned with the landing pad 319. The gap 149 may have a width G that is equal to or less than the width of the landing pad 319. As being described below in more details, the gap 149 between the first and the second recess 141 and 142 may be used as a guiding window in a process of creating via opening for forming a through via landing on the landing pad 319.

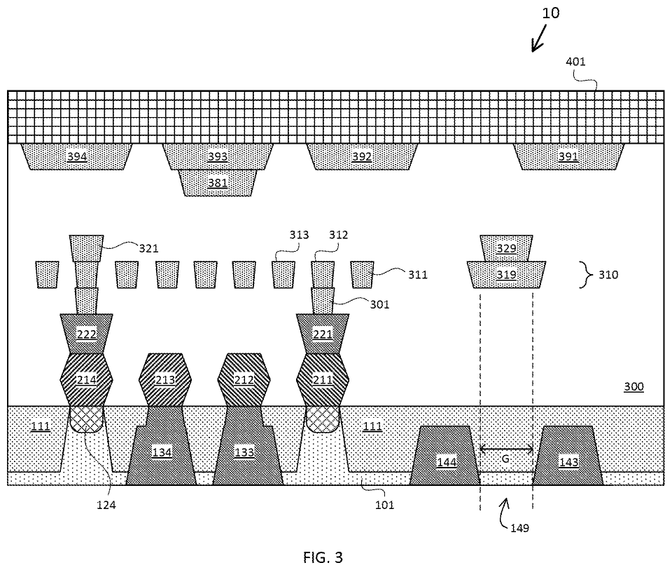

FIG. 3 is a demonstrative illustration of cross-sectional view of a semiconductor structure in a step of manufacturing thereof according to one embodiment of present invention. More particularly, following the step illustrated in FIG. 2, embodiments of present invention provide filling the first and the second backside contact opening 131 and 132 with a conductive material to form a first and a second backside S/D contact 133 and 134, and filling the first and the second recess 141 and 142 with the conductive material to form a first and a second dummy contact 143 and 144. In the follow-up process of creating via opening, the first and the second dummy contact 143 and 144 may work as guiding pads in strategically aligning the via opening with the landing pad 319 therefore the first and the second dummy contact 143 and 144 may also be known as a first and a second guiding pad. The first and the second backside S/D contact 133 and 134 and the first and the second dummy contact 143 and 144 may be formed in a same deposition process of the conductive material. After the deposition, a chemical-mechanical-polishing (CMP) process may be applied to remove any excess conductive material on top of the semiconductor substrate 101 and planarize a top surface of the substrate 101. The first and the second dummy contact 143 and 144 are horizontally aligned with the first and the second backside S/D contact 133 and 134. In one embodiment, the first and the second dummy contact 143 and 144 and the first and the second backside S/D contact 133 and 134 have a coplanar top surface.

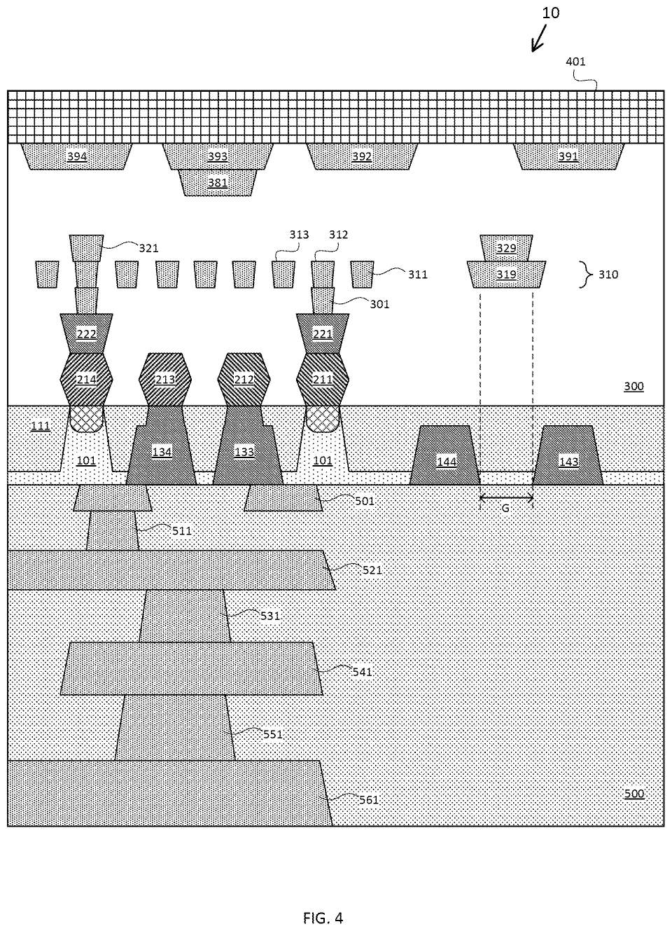

FIG. 4 is a demonstrative illustration of cross-sectional view of a semiconductor structure in a step of manufacturing thereof according to one embodiment of present invention. More particularly, following the step illustrated in FIG. 3, embodiments of present invention provide forming various backside metal lines and backside vias to form a backside power distribution network (BSPDN). The BSPDN may include, for example, a first backside metal level 501; a second backside metal level 521 conductively connected to the first backside metal level 501 through, for example, a backside via 511; a third backside metal level 541 conductively connected to the second backside metal level 521 through, for example, a backside via 531; and a fourth backside metal level 561 conductively connected to the third backside metal level 541 through, for example, a backside via 551. The BSPDN may be embedded in a backside dielectric layer 500.

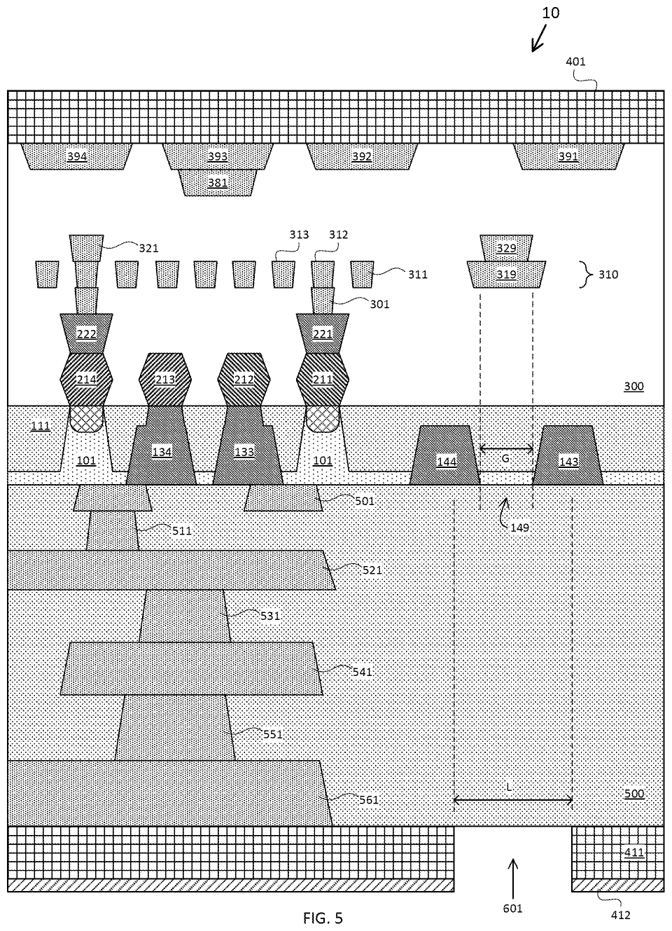

FIG. 5 is a demonstrative illustration of cross-sectional view of a semiconductor structure in a step of manufacturing thereof according to one embodiment of present invention. More particularly, following the step illustrated in FIG. 4, embodiments of present invention provide patterning the backside dielectric layer 500 through, for example, a lithographic patterning process. More particularly, a hard mask layer 411 such as an organic planarization layer (OPL) may first be deposited on top of the backside dielectric layer 500 and an anti-reflection-coating (ARC) layer 412 may be formed on top of the hard mask layer 411. The hard mask layer 411 may then be patterned, through a lithographic patterning and a selective etch process, to have a mask opening 601. The mask opening 601 created in the hard mask layer 411, through the ARC layer 412, may be vertically substantially aligned with the gap 149 between the first dummy contact 143 and the second dummy contact 144. For example, the mask opening 601 may have a horizontal width L that is equal to or wider than the width G of the gap 149. In other words, the mask opening 601 may fully overlap with the gap 149.

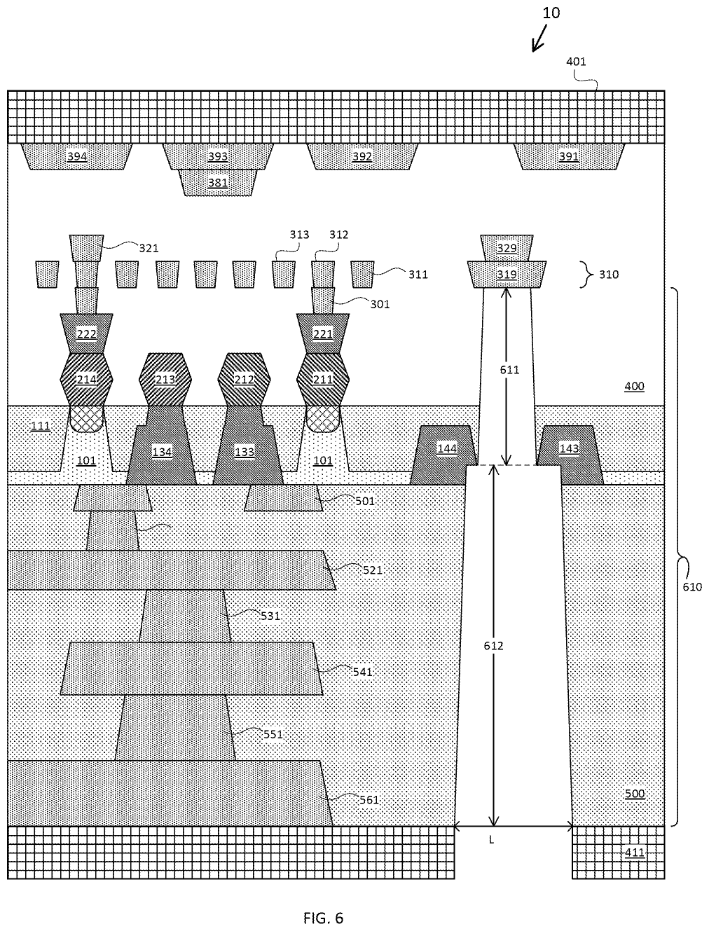

FIG. 6 is a demonstrative illustration of cross-sectional view of a semiconductor structure in a step of manufacturing thereof according to one embodiment of present invention. More particularly, following the step illustrated in FIG. 5, embodiments of present invention provide selectively etching the backside dielectric layer 500, through the mask opening 601 in the hard mask layer 411, and subsequently etching the semiconductor substrate 101, the STI 111, and the dielectric layer 400, through the gap 149 between the first and the second dummy contact 143 and 144, to create a via opening 610. The via opening 610 may stop at thereby expose the landing pad 319 at the first metal level 310.

More particularly, embodiments of present invention provide first etching the backside dielectric layer 500 to create a second portion 612 of the via opening 610. The second portion 612 of the via opening 610 may expose the gap 149 between the first and the second dummy contact 143 and 144, and at least a portion of the first and the second dummy contact 143 and 144. The first and the second dummy contact 143 and 144 may have an etch selectivity that is significantly different from that of the backside dielectric layer 500 and other surrounding materials such as the semiconductor substrate 101, the STI 111, and the dielectric layer 400. In other words, the first and the second dummy contact 143 and 144 may not be etched by the selective etch process, remain substantially unetched during the etch process. Embodiments of present invention provide applying the first and the second dummy contact 143 and 144 as guiding pads in a subsequent etch process in creating a first portion 611 of the via opening 610.

Embodiments of present invention provide selectively etching the semiconductor substrate 101, the STI 111, and the dielectric layer 400 exposed by the second portion 612 of the via opening 610 and in the region of the gap 149 between the first and the second dummy contact 143 and 144. By being selective to the first and the second dummy contact 143 and 144, the etch process may continue to create the first portion 611 of the via opening 610 in the region exposed by the gap 149. Because the gap 149 is strategically aligned with the landing pad 319, the first portion 611 of the via opening 610 may fully land on the landing pad 319.

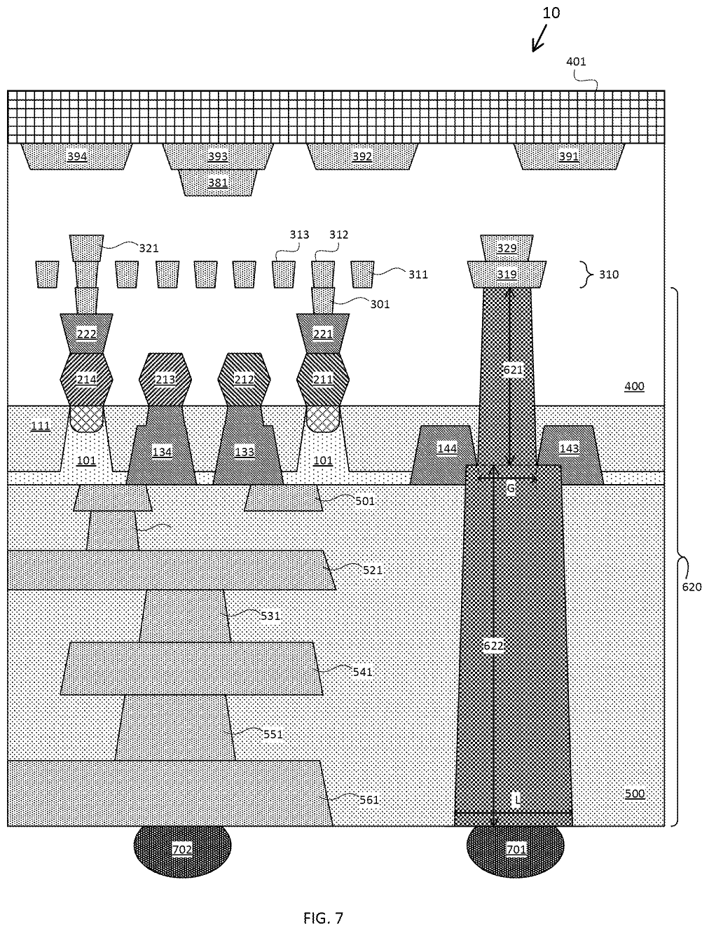

FIG. 7 is a demonstrative illustration of cross-sectional view of a semiconductor structure in a step of manufacturing thereof according to one embodiment of present invention. More particularly, following the step illustrated in FIG. 6, embodiments of present invention provide filling the via opening 610 with a conductive material, for example, in a deposition process. The deposition process may thus create a through via 620, also known as a through silicon via (TSV), and the through via 620 may include a first portion 621 and a second portion 622 of a same conductive material, with the second portion 621 being directly on top of the first portion 621 at the first and the second dummy contact 143 and 144. The first portion 621 of the through via 620 may have a width G that is defined by the width of the gap 149 between the first and the second dummy contact 143 and 144, while the second portion 622 of the through via 620 may have a width L that is wider than that of the first portion 621. The second portion 622 of the through via 620 may partially land on top of the first and the second dummy contact 143 and 144, resulting in the through via 620 having a discontinuous increase in width from the first portion 621 to the second portion 622. The discontinuous increase in width of the through via 620 coincides with a location of the first and the second guiding pad. For example, the first portion 621 of the through via 620 may generally have a width G and the second portion 622 of the through via 620 may generally have a width L and L is larger than G. For example, G may be between about 20 nm and about 450 nm, and L may be between about 40 nm and about 600 nm. In one embodiment, the second portion 622 of the through via 620 has a width L that is at least 5% more than a width G of the first portion 621 of the through via 620.

In one embodiment, the first portion 621 of the through via 620 may have a depth of about 5% to 20% of a depth of the through via 620. For example, the first portion 621 may have a depth ranging from about 200 nm to about 400 nm, and the second portion 622 may have a depth ranging from about 1000 nm to about 5000 nm.

Embodiments of present invention may provide forming additional backside metal levels or other conductive structures above and in contact with the through via 620. In one embodiment, the through via 620 may be in contact with one of the one or more backside metal levels 501, 521, 541, or 561 of the BSPDN. In another embodiment, C4 solder may be formed on top of and in contact with the through via 620 and other backside metal levels. For example, a first C4 solder 701 may be formed on top of the second portion 622 of the through via 620 and a second C4 solder 702 may be formed to be in contact with the fourth backside metal level 561. In other words, the through via 620 is either connected to one of the backside metal levels of the BSPDN or connected to a C4 solder.

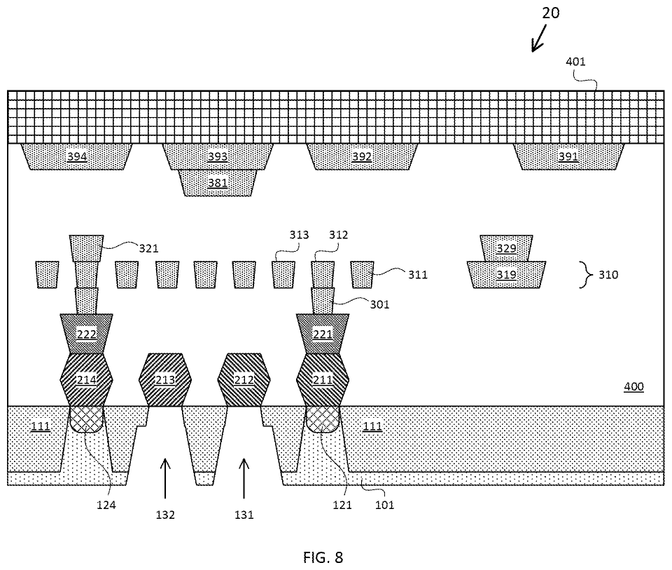

FIG. 8 is a demonstrative illustration of cross-sectional view of a semiconductor structure in a step of manufacturing thereof according to another embodiment of present invention. More particularly, starting from the semiconductor structure 10 demonstratively illustrated in FIG. 1, embodiments of present invention provide forming a semiconductor structure 20 by creating the first and the second backside contact opening 131 and 132 to expose bottom surfaces of the S/D regions 212 and 213 of the one or more transistors. Different from the previous embodiment, no additional recesses may be created at this stage. Hereinafter, similar to the previous embodiment, processing of the semiconductor structure 20 is performed from the backside of the semiconductor substrate 101 and the description is so provided as if the semiconductor substrate 101 is flipped upside-down. Nevertheless, for the convenience of illustration, drawings of FIGS. 8-13 may continue to be provided in an upside-up fashion.

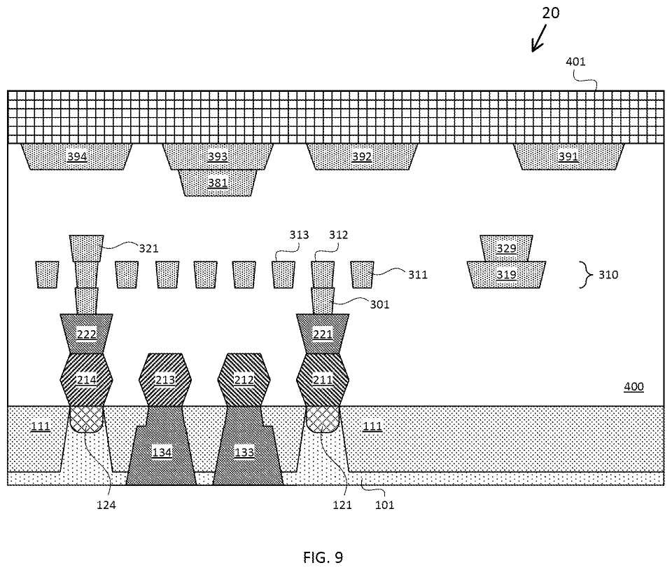

FIG. 9 is a demonstrative illustration of cross-sectional view of a semiconductor structure in a step of manufacturing thereof according to one embodiment of present invention. More particularly, following the step illustrated in FIG. 8, embodiments of present invention provide filling the first and the second backside contact opening 131 and 132 with a conductive material to form a first and a second backside S/D contact 133 and 134, removing any excessive conductive material, and planarize a top surface of the substrate 101.

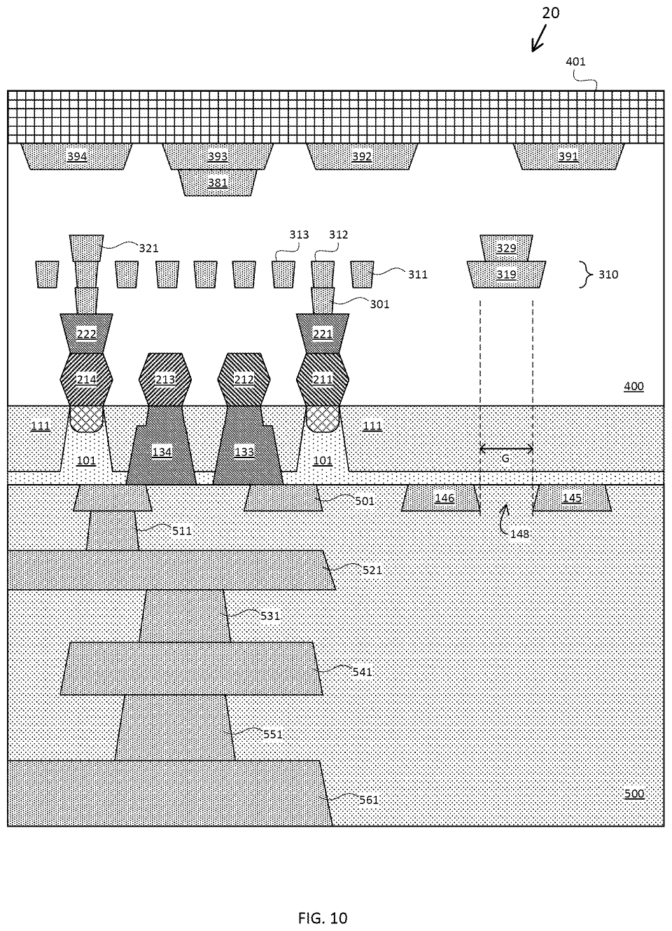

FIG. 10 is a demonstrative illustration of cross-sectional view of a semiconductor structure in a step of manufacturing thereof according to one embodiment of present invention. More particularly, following the step illustrated in FIG. 9, embodiments of present invention provide forming various backside metal lines and backside vias to form a backside power distribution network (BSPDN). The BSPDN may include, for example, a first backside metal level 501; a second backside metal level 521 conductively connected to the first backside metal level 501 through, for example, a backside via 511; a third backside metal level 541 conductively connected to the second backside metal level 521 through, for example, a backside via 531; and a fourth backside metal level 561 conductively connected to the third backside metal level 541 through, for example, a backside via 551. The BSPDN may be embedded in a backside dielectric layer 500.

According to one embodiment of present invention, in the process of forming the BSPDN, additional metal lines such as a first dummy metal line 145 and a second dummy metal line 146 may be formed. The first and the second dummy metal line 145 and 146 may be formed at the first backside metal level 501 (BM1). However, embodiments of present invention are not limited in this aspect and the first and the second dummy metal line 145 and 146 may be formed at other backside metal levels such as BM2, BM3, etc. When being formed at the first backside metal level 501, the first and the second dummy metal line 145 and 146 may be horizontally substantially aligned with metal lines of the first backside metal level 501. For example, in one embodiment, the first and the second dummy metal line 145 and 146 and metal lines of the first backside metal level 501 may have a coplanar top surface.

The first and the second dummy metal line 145 and 146 may be made strategically such that a gap 148 between the first dummy metal line 145 and the second dummy metal line 146 may be vertically aligned with the landing pad 319. The gap 148 may have a width G that is equal to or less than the width of the landing pad 319. As being described below in more details, the gap 148 between the first and the second dummy metal line 145 and 146 may be used as a guiding window in a process of creating via opening for forming a through via landing on the landing pad 319.

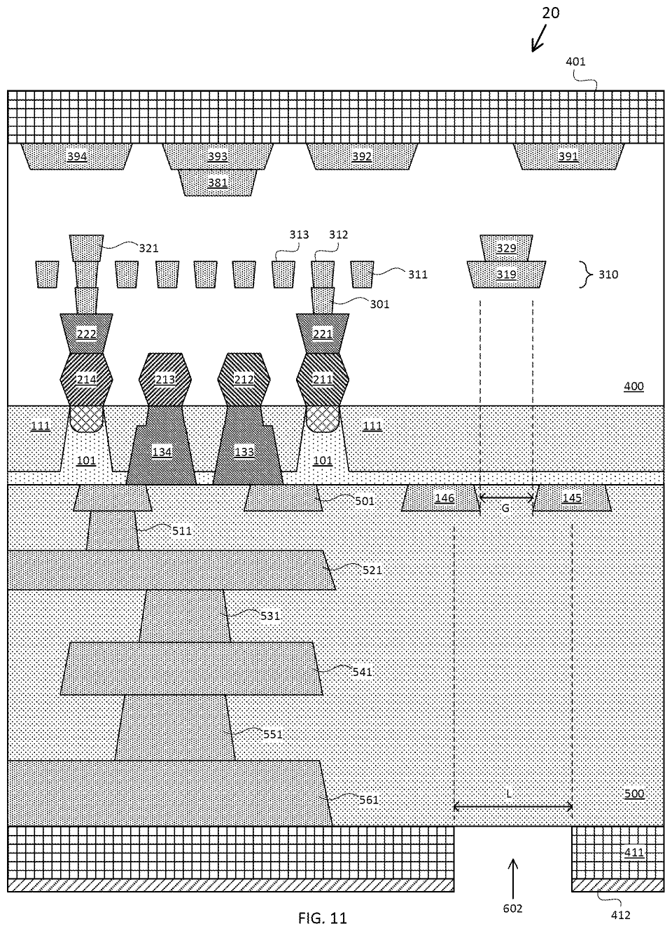

FIG. 11 is a demonstrative illustration of cross-sectional view of a semiconductor structure in a step of manufacturing thereof according to one embodiment of present invention. More particularly, following the step illustrated in FIG. 10, embodiments of present invention provide patterning the backside dielectric layer 500 through, for example, a lithographic patterning process. More particularly, a hard mask layer 411 such as an organic planarization layer (OPL) may first be deposited on top of the backside dielectric layer 500 and an anti-reflection-coating (ARC) layer 412 may be formed on top of the hard mask layer 411. The hard mask layer 411 may then be patterned, through a lithographic patterning and a selective etch process, to have a mask opening 602. The mask opening 602 created in the hard mask layer 411, through the ARC layer 412, may be vertically substantially aligned with the gap 148 between the first dummy metal line 145 and the second dummy metal line 146. For example, the mask opening 602 may have a horizontal width L that is equal to or wider than the width G of the gap 148. In other words, the mask opening 602 may fully overlap with the gap 148.

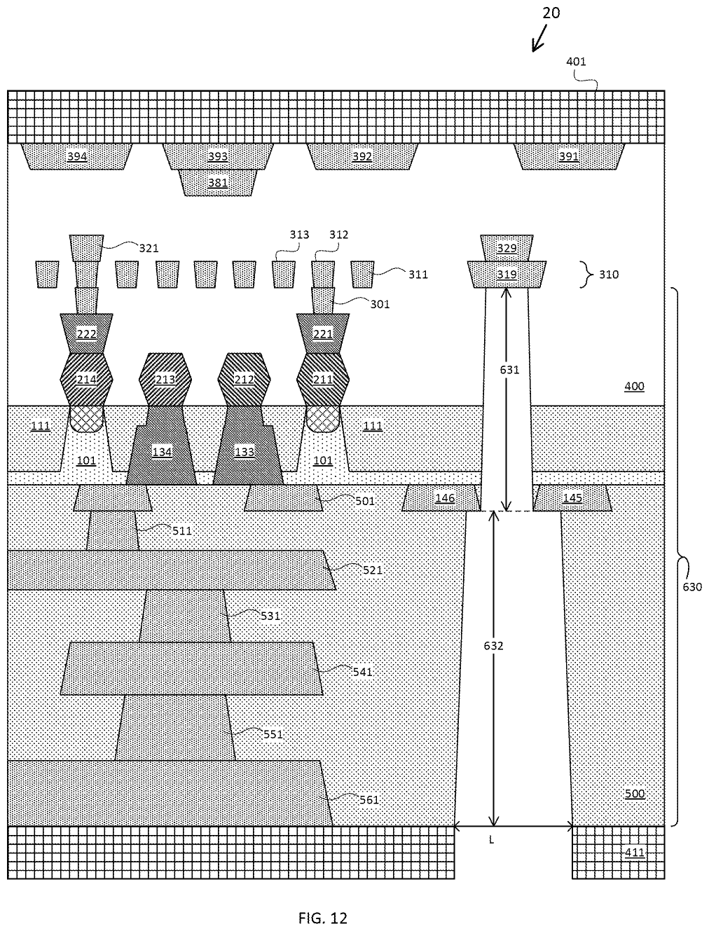

FIG. 12 is a demonstrative illustration of cross-sectional view of a semiconductor structure in a step of manufacturing thereof according to one embodiment of present invention. More particularly, following the step illustrated in FIG. 11, embodiments of present invention provide selectively etching the backside dielectric layer 500, through the mask opening 602 in the hard mask layer 411, and subsequently etching the semiconductor substrate 101, the STI 111, and the dielectric layer 400, through the gap 148 between the first and the second dummy metal line 145 and 146, to create a via opening 630. The via opening 630 may stop at, thereby expose, the landing pad 319 at the first metal level 310.

More particularly, embodiments of present invention provide first etching the backside dielectric layer 500 to create a second portion 632 of the via opening 630. The second portion 632 of the via opening 630 may expose the gap 148 between the first and the second dummy metal line 145 and 146, and at least a portion of the first and the second dummy metal line 145 and 146. The first and the second dummy metal line 145 and 146 may have an etch selectivity that is significantly different from that of the backside dielectric layer 500. In other words, the first and the second dummy metal line 145 and 146 may not be etched by the selective etch process and may remain substantially unetched during the etch process. Embodiments of present invention provide applying the first and the second dummy metal line 145 and 146 as guiding pads in a subsequent etch process in creating a first portion 631 of the via opening 630.

Embodiments of present invention provide continuing to etch the backside dielectric layer 500 between the first and the second dummy metal line 145 and 146, which works as guiding pads and thus may be known as a first and a second guiding pads. More particularly, embodiments of present invention provide etch the semiconductor substrate 101, the STI 111, and the dielectric layer 400 subsequently exposed by the second portion 632 of the via opening 630 and in the region of the gap 148 between the first and the second dummy metal line 145 and 146. By being selective to the first and the second dummy metal line 145 and 146, the etch process may continue to create the first portion 631 of the via opening 630 in the region exposed by the gap 148. Because the gap 148 is strategically aligned with the landing pad 319, the first portion 631 of the via opening 630 may fully land on the landing pad 319.

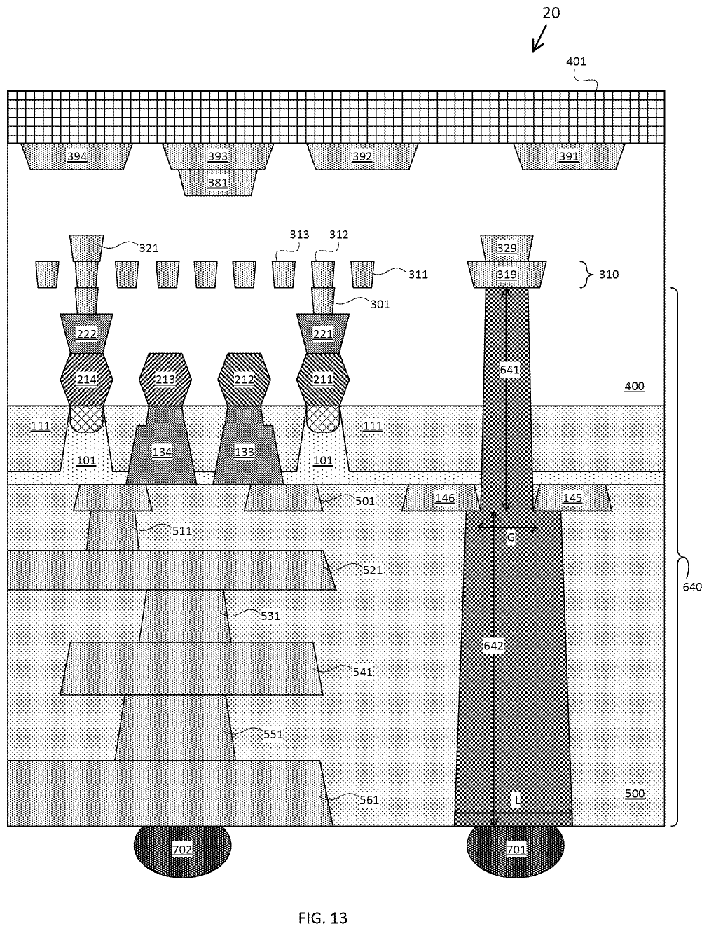

FIG. 13 is a demonstrative illustration of cross-sectional view of a semiconductor structure in a step of manufacturing thereof according to one embodiment of present invention. More particularly, following the step illustrated in FIG. 12, embodiments of present invention provide filling the via opening 630 with a conductive material, for example, in a deposition process. The deposition process may thus create a through via 640, and the through via 640 may include a first portion 641 and a second portion 642 of a same conductive material, with the second portion 642 being directly on top of the first portion 641 at the first and the second dummy metal line 145 and 146. The through via 640 may also be known as a TSV. The first portion 641 of the through via 640 may have a width G that is defined by the width of the gap 148 between the first and the second dummy metal line 145 and 146, while the second portion 642 of the through via 640 may have a width L that is wider than that of the first portion 641. The second portion 642 of the through via 640 may partially land on top of the first and the second dummy metal line 145 and 146, resulting in the through via 640 having a discontinuous increase in width from the first portion 641 to the second portion 642. For example, the first portion 641 of the through via 640 may generally have a width G and the second portion 642 of the through via 640 may generally have a width L and L is larger than G. For example, G may be between about 20 nm and about 450 nm, and L may be between about 40 nm and about 600 nm. In one embodiment, the first portion 641 of the through via 640 may have a depth of about 5% to 20% of a depth of the through via 640. For example, the first portion 641 may have a depth ranging from about 20 nm to 400 nm, and the second portion 642 may have a depth ranging from about 1000 nm to about 5000 nm.

Embodiments of present invention may provide forming additional backside metal levels or other conductive structures above and in contact with the through via 640. In one embodiment, C4 solders may be formed on top of and in contact with the through via 640 and other backside metal levels. For example, a first C4 solder 701 may be formed on top of the second portion 642 of the through via 640 and a second C4 solder 702 may be formed to be in contact with the fourth backside metal level 561. In other words, the through via 640 is either connected to one of the backside metal levels of the BSPDN or connected to a C4 solder.

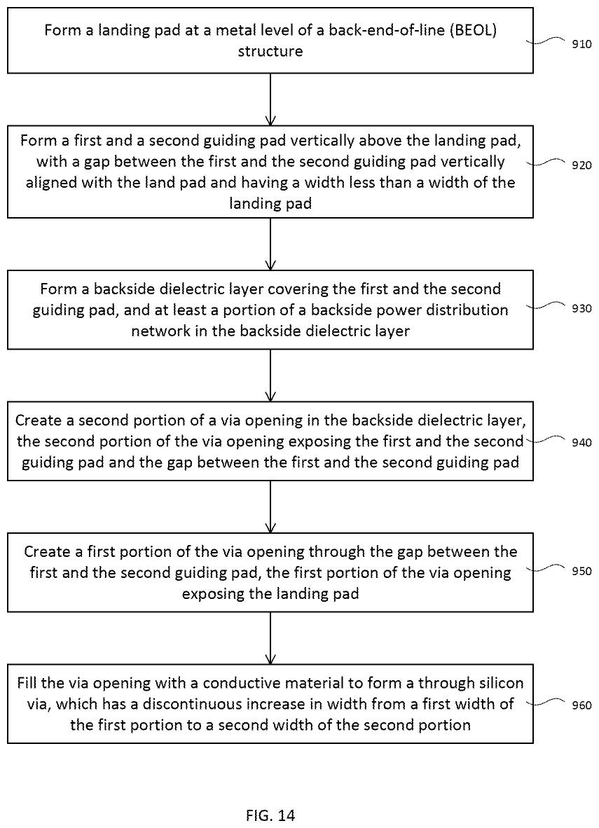

FIG. 14 is a demonstrative illustration of a flow-chart of a method of manufacturing a semiconductor structure according to embodiments of present invention. The method includes (910) forming a landing pad at a metal level of a back-end-of-line (BEOL) structure; (920) forming a first and a second guiding pad vertically above the landing pad, with a gap between the first and the second guiding pad vertically aligned with the land pad and having a width less than a width of the landing pad; (930) forming a backside dielectric layer covering the first and the second guiding pad, and at least a portion of a backside power distribution network in the backside dielectric layer; (940) creating a second portion of a via opening in the backside dielectric layer, the second portion of the via opening exposing the first and the second guiding pad and the gap between the first and the second guiding pad; (950) creating a first portion of the via opening through the gap between the first and the second guiding pad, the first portion of the via opening exposing the landing pad; and (960) filling the via opening with a conductive material to form a through silicon via, the through silicon via having a discontinuous increase in width from a first width of the first portion to a second width of the second portion.

Various examples may possibly be described by one or more of the following features in the following numbered clauses:

Clause 1: A semiconductor structure comprising: a first metal level in a back-end-of-line (BEOL) structure; a second metal level in a backside power distribution network (BSPDN); and a through silicon via (TSV) extending from the second metal level to the first metal level, wherein the TSV has a first portion and a second portion and a discontinuous increase in width from the first portion to the second portion.

Clause 2: The semiconductor structure of clause 1, further comprising a landing pad at the first metal level, wherein the landing pad has a width that is wider than a width of the first portion of the TSV and the first portion of the TSV fully lands on the landing pad at the first metal level.

Clause 3: The semiconductor structure of clause 1, further comprising a first guiding pad and a second guiding pad and a gap between the first guiding pad and the second guiding pad, wherein a width of the first portion of the TSV is substantially same as a width of the gap.

Clause 4: The semiconductor structure of clause 3, wherein the first and the second guiding pad are horizontally aligned with one or more backside source/drain contacts of one or more transistors.

Clause 5: The semiconductor structure of clause 3, wherein the first and the second guiding pad are horizontally aligned with one of one or more backside metal levels of the BSPDN.

Clause 6: The semiconductor structure of clause 3, wherein the second portion of the TSV partially lands on the first and the second guiding pad such that the discontinuous increase in width of the TSV coincides with a location of the first and the second guiding pad.

Clause 7: The semiconductor structure of clause 1, wherein the first portion of the TSV has a first width, and the second portion of the TSV has a second width, and the second width is at least 5% more than the first width.

Clause 8: A method of forming a semiconductor structure comprising: forming a landing pad at a metal level of a back-end-of-line (BEOL) structure; forming a first and a second guiding pad vertically above the landing pad; forming a backside dielectric layer covering the first and the second guiding pad; creating a second portion of a via opening in the backside dielectric layer, the second portion of the via opening exposing a portion of the first and the second guiding pad and a gap between the first and the second guiding pad; creating a first portion of the via opening through the gap between the first and the second guiding pad, the first portion of the via opening exposing the landing pad; and filling the via opening with a conductive material to form a through silicon via (TSV).

Clause 9: The method of clause 8, wherein the gap between the first and the second guiding pad is substantially aligned with the landing pad and a width of the gap is equal to or less than a width of the landing pad.

Clause 10: The method of clause 8, wherein forming the first and the second guiding pad comprises forming a first and a second dummy contact, the first and the second dummy contact are horizontally aligned with one or more backside source/drain contact of one or more transistors.

Clause 11: The method of clause 8, wherein forming the first and the second guiding pad comprises forming a first and a second dummy metal line, the first and the second dummy metal line are horizontally aligned with one of one or more backside metal levels of a backside power distribution network.

Clause 12: The method of clause 8, wherein creating the first portion of the via opening comprises etching a region in the gap between the first and the second guiding pad in an etch process that is selective to the first and the second guiding pad.

Clause 13: The method of clause 8, further comprising forming a backside power distribution network in the backside dielectric layer and a C4 solder.

Clause 14: The method of clause 13, wherein the TSV is either connected to the BSPDN or connected to the C4 solder.

Clause 15: A semiconductor structure comprising: a landing pad in a back-end-of-line (BEOL) structure; a backside power distribution network (BSPDN) in a backside dielectric layer; and a through silicon via (TSV) extending from the backside dielectric layer to the landing pad in the BEOL structure, wherein the TSV has a first portion of a first width and a second portion of a second width and a discontinuous increase in width from the first width of the first portion to the second width of the second portion, the second width being at least 5% larger than the first width.

Clause 16: The semiconductor structure of clause 15, wherein the first portion of the TSV is directly contact with the landing pad, and the landing pad is at one of one or more metal levels of the BEOL structure and has a width that is wider than the first width of the first portion of the TSV.

Clause 17: The semiconductor structure of clause 15, further comprising a first guiding pad and a second guiding pad and a gap between the first guiding pad and the second guiding pad, wherein the first width of the first portion of the TSV is substantially same as a width of the gap.

Clause 18: The semiconductor structure of clause 17, further comprising one or more backside source/drain contacts of one or more transistors, wherein the first and the second guiding pad and the one or more backside source/drain contacts have a coplanar surface.

Clause 19: The semiconductor structure of clause 17, wherein the BSPDN has a backside metal level, and wherein the first and the second guiding pad and the backside metal level has a coplanar surface.

Clause 20: The semiconductor structure of clause 15, further comprising a C4 solder, wherein the TSV is either connected to the BSPDN or the C4 solder.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising:
a first metal level in a back-end-of-line (BEOL) structure;
a second metal level in a backside power distribution network (BSPDN); and
a through silicon via (TSV) extending from the second metal level to the first metal level,
wherein the TSV has a first portion and a second portion and a discontinuous increase in width from the first portion to the second portion.

2. The semiconductor structure of claim 1, further comprising a landing pad at the first metal level, wherein the landing pad has a width that is wider than a width of the first portion of the TSV and the first portion of the TSV fully lands on the landing pad at the first metal level.

3. The semiconductor structure of claim 1, further comprising a first guiding pad and a second guiding pad and a gap between the first guiding pad and the second guiding pad, wherein a width of the first portion of the TSV is substantially same as a width of the gap.

4. The semiconductor structure of claim 3, wherein the first and the second guiding pad are horizontally aligned with one or more backside source/drain contacts of one or more transistors.

5. The semiconductor structure of claim 3, wherein the first and the second guiding pad are horizontally aligned with one of one or more backside metal levels of the BSPDN.

6. The semiconductor structure of claim 3, wherein the second portion of the TSV partially lands on the first and the second guiding pad such that the discontinuous increase in width of the TSV coincides with a location of the first and the second guiding pad.

7. The semiconductor structure of claim 1, wherein the first portion of the TSV has a first width, and the second portion of the TSV has a second width, and the second width is at least 5% more than the first width.

8. A method of forming a semiconductor structure comprising:
forming a landing pad at a metal level of a back-end-of-line (BEOL) structure;
forming a first and a second guiding pad vertically above the landing pad;
forming a backside dielectric layer covering the first and the second guiding pad;
creating a second portion of a via opening in the backside dielectric layer, the second portion of the via opening exposing a portion of the first and the second guiding pad and a gap between the first and the second guiding pad;
creating a first portion of the via opening through the gap between the first and the second guiding pad, the first portion of the via opening exposing the landing pad; and
filling the via opening with a conductive material to form a through silicon via (TSV).

9. The method of claim 8, wherein the gap between the first and the second guiding pad is substantially aligned with the landing pad and a width of the gap is equal to or less than a width of the landing pad.

10. The method of claim 8, wherein forming the first and the second guiding pad comprises forming a first and a second dummy contact, the first and the second dummy contact are horizontally aligned with one or more backside source/drain contact of one or more transistors.

11. The method of claim 8, wherein forming the first and the second guiding pad comprises forming a first and a second dummy metal line, the first and the second dummy metal line are horizontally aligned with one of one or more backside metal levels of a backside power distribution network.

12. The method of claim 8, wherein creating the first portion of the via opening comprises etching a region in the gap between the first and the second guiding pad in an etch process that is selective to the first and the second guiding pad.

13. The method of claim 8, further comprising forming a backside power distribution network in the backside dielectric layer and a C4 solder.

14. The method of claim 13, wherein the TSV is either connected to the BSPDN or connected to the C4 solder.

15. A semiconductor structure comprising:
a landing pad in a back-end-of-line (BEOL) structure;
a backside power distribution network (BSPDN) in a backside dielectric layer; and
a through silicon via (TSV) extending from the backside dielectric layer to the landing pad in the BEOL structure,
wherein the TSV has a first portion of a first width and a second portion of a second width and a discontinuous increase in width from the first width of the first portion to the second width of the second portion, the second width being at least 5% larger than the first width.

16. The semiconductor structure of claim 15, wherein the first portion of the TSV is directly contact with the landing pad, and the landing pad is at one of one or more metal levels of the BEOL structure and has a width that is wider than the first width of the first portion of the TSV.

17. The semiconductor structure of claim 15, further comprising a first guiding pad and a second guiding pad and a gap between the first guiding pad and the second guiding pad, wherein the first width of the first portion of the TSV is substantially same as a width of the gap.

18. The semiconductor structure of claim 17, further comprising one or more backside source/drain contacts of one or more transistors, wherein the first and the second guiding pad and the one or more backside source/drain contacts have a coplanar surface.

19. The semiconductor structure of claim 17, wherein the BSPDN has a backside metal level, and wherein the first and the second guiding pad and the backside metal level has a coplanar surface.

20. The semiconductor structure of claim 15, further comprising a C4 solder, wherein the TSV is either connected to the BSPDN or the C4 solder.
